(19) United States
(12) Patent Application Publication
(10) Pub. No.: US 2014/0313038 A1
(43) Pub. Date: Oct. 23, 2014

(54) DETECTION DEVICE

(71) Applicants: HONG FU JIN PRECISION INDUSTRY (ShenZhen) CO., LTD., ShenZhen (CN); HON HAI PRECISION INDUSTRY CO., LTD., New Taipei (TW)

(72) Inventor: HAI-QING ZHOU, Shenzhen (CN)

(73) Assignees: HONG FU JIN PRECISION INDUSTRY (ShenZhen) CO., LTD., ShenZhen (CN); HON HAI PRECISION INDUSTRY CO., LTD., New Taipei (TW)

(21) Appl. No.: 14/253,986

(22) Filed: Apr. 16, 2014

(30) Foreign Application Priority Data
Apr. 18, 2013 (CN) 2013101359799

(51) Int. Cl. G01R 31/02; G08B 21/18

(52) U.S. Cl. CPC G01R 31/025; G08B 21/182; G08B 21/185
USPC 340/584

(57) ABSTRACT

A detection device includes a detection circuit and a temperature measuring device. The detection circuit is used to detect an electronic component causing a short circuit in a circuit module and includes a power source, a light emitting diode (LED), a first connecting terminal connected to a cathode of the LED, and a second connecting terminal An anode of the LED is connected to an anode terminal of the power source. The first connecting terminal and the second connecting terminal are connected the first node and the second node, respectively. The temperature measuring device includes a number of test terminals for contacting the electronic components to measure and show temperatures of the electronic components. If a short circuit occurs, the LED is turned on. The short circuited electronic component is identified by reading the temperatures of the test terminals.

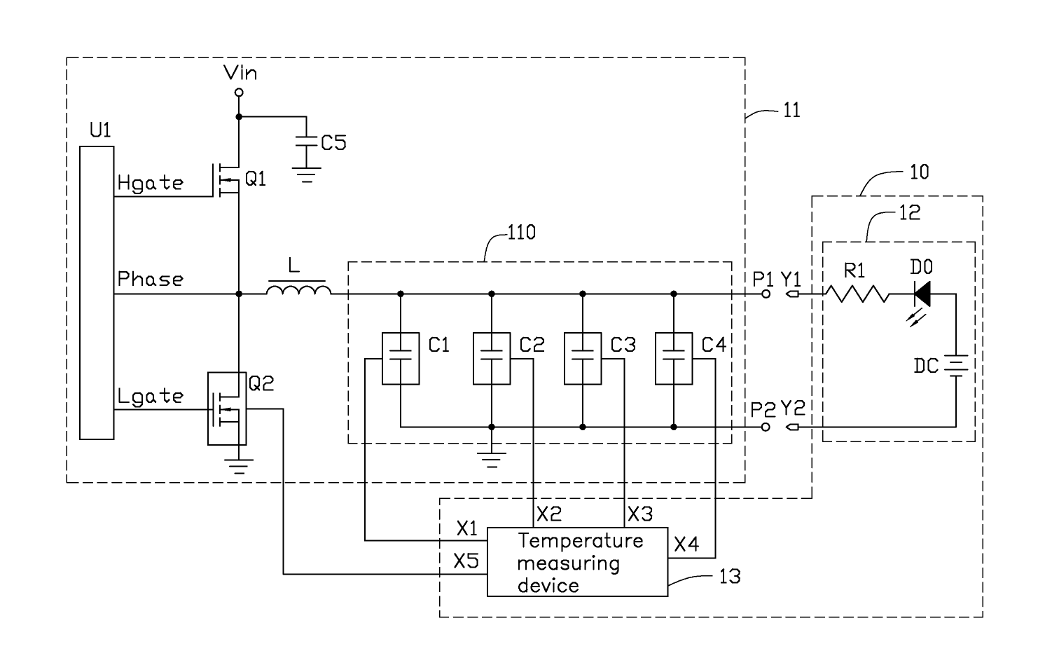

### FIELD

The present disclosure relates to a detection device.

### BACKGROUND

When a short circuit occur in a circuit, it is difficult to detect which electronic component of the circuit caused the short circuit, especially when the circuit comprises a plurality of electronic components connected in parallel.

### BRIEF DESCRIPTION OF THE DRAWINGS

Many aspects of the present disclosure can be better understood with reference to the following drawing(s). The electronic components in the drawing(s) are not necessarily drawn to scale, the emphasis instead being placed upon clearly illustrating the principles of the present disclosure. Moreover, in the drawing(s), like reference numerals designate corresponding parts throughout the several views.

The figure is a circuit diagram of an embodiment of a detection device of the present disclosure.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.” The references “a plurality of” and “a number of” mean “at least two.”

The figure shows a circuit diagram of an embodiment of a detection device 10 used to detect electronic components of a circuit module 11 causing short circuits. The detection device 10 can include a detection circuit 12 and a temperature measuring device 13.

In this embodiment, the circuit module 11 powers a central processing unit (CPU) on a motherboard. The circuit module 11 includes a control chip U1, electronic switches Q1 and Q2, an inductor L, a capacitor C5, a first node P1, a second node P2, and a parallel unit 110. The electronic switches Q1, Q2 are n-channel metal-oxide semiconductor field-effect transistors (MOSFETs). The parallel unit 110 includes a plurality of electronic components connected in parallel. In the embodiment, the electronic components are four capacitors C1-C4.

A gate of the electronic switch Q1 is electrically connected to a pin Hgate of the control chip U1. A drain of the electronic switch Q1 is electrically connected to a power source Vin to receive an operation voltage. The drain of the electronic switch Q1 is also grounded though the capacitor C5. A gate of the electronic switch Q2 is electrically connected to a pin Lgate of the control chip U1. A drain of the electronic switch Q2 is electrically connected to a source of the electronic switch Q1. A source of the electronic switch Q2 is grounded. A pin Phase of the control chip U1 is electrically connected to the source of the electronic switch Q1 and the drain of the electronic switch Q2. Each of the capacitors C1-C4 includes an anode and a cathode. The pin Phase of the control chip U1 is also electrically connected to the anodes of the capacitors C1-C4 through the inductor L. The cathodes of capacitors C1-C4 are grounded. The anodes of the capacitors C1-C4 are electrically connected to the first node P1, and the cathodes of the capacitors C1-C4 are electrically connected to the second node P2.

The detection circuit 12 includes a power source DC, a light emitting diode (LED) D0, a resistor R1, a first connecting terminal Y1, and a second connecting terminal Y2. In one embodiment, the power source DC is a direct current power source. An anode of the LED D0 is electrically connected to an anode of the power source DC. A cathode of the LED D0 is electrically connected to the first connecting terminal Y1 through the resistor R1. A cathode of the power source DC is electrically connected to the second connecting terminal Y2.

In use, the first and second connecting terminals Y1, Y2 are electrically connected to the first and second nodes P1, P2 of the circuit module 11, respectively. If a short circuit occurs, the LED D0 is turned on. If a short circuit does not occur, the LED D0 does not turn on.

The temperature measuring device 13 includes a plurality of test terminals X1-X5. The test terminals X1-X5 contact surfaces of the electronic components of the circuit module 11. In the embodiment, the test terminals X1-X5 contact surfaces of the capacitors C1-C4 and the electronic switch Q2, respectively. The temperature measuring device 13 shows temperatures of the capacitors C1-C4 and of the electronic switch Q2. Thus, when a short circuit occurs, the short circuited electronic component can be conveniently identified by reading the temperatures of the test terminals X1-X5.

While the disclosure has been described by way of example and in terms of the embodiment, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A detection device for detecting an electronic component of a circuit module causing a short circuit, the circuit module comprising a first node, a second node, and a plurality of electronic components electrically connected in parallel between the first and second nodes, the detection device comprising:
a detection circuit comprising a power source, a light emitting diode (LED), a first connecting terminal electrically connected to a cathode of the LED, an anode of the LED which is electrically connected to an anode terminal of the power source, and a second connecting terminal electrically connected to a cathode of the power source, wherein the first connecting terminal and the second terminal are electrically connected the first node and the second node respectively; and
a temperature measuring device comprising a plurality of test terminals contacting the electronic components respectively to measure and show temperatures of the electronic components,
wherein when the short circuit occurs, the LED is turned on, the temperature of at least one of the plurality of electronic components increases over a predetermined value, and a short circuited electronic component is identified by reading the temperatures of the test terminals.

2. The detection device of claim 1, wherein the cathode of the LED is electrically connected to the first test terminal through a first resistor.

3. The detection device of claim 2, wherein the electronic components are four capacitors C1-C4.
